(19) United States
(12) Patent Application Publication
(10) Pub. No.: US 2015/0102410 A1
(43) Pub. Date: Apr. 16, 2015

(54) SEMICONDUCTOR DEVICE INCLUDING STRESS LAYER ADJACENT CHANNEL AND RELATED METHODS

(71) Applicants: GLOBALFOUNDRIES INC, Grand Cayman (KY); STMicroelectronics, Inc., Coppell, TX (US)

(72) Inventors: QING LIU, Guilderland, NY (US); Xiuyu Cai, Niskayuna, NY (US); Ruilong Xie, Schenectady, NY (US)

(73) Assignees: GLOBALFOUNDRIES INC, Grand Cayman (KY); STMicroelectronics, Inc., Coppell, TX (US)

(21) Appl. No.: 14/050,666

(22) Filed: Oct. 10, 2013

(51) Int. Cl. H01L 29/78; H01L 29/786; H01L 29/66

(52) U.S. Cl. CPC H01L 29/7843; H01L 29/6653; H01L 29/786
USPC 257/347; 438/151

(57) ABSTRACT

A method for making a semiconductor device may include forming a gate on a semiconductor layer, forming sidewall spacers adjacent the gate, and forming raised source and drain regions defining a channel in the semiconductor layer under the gate. The raised source and drain regions may be spaced apart from the gate by the sidewall spacers. The method may further include removing the sidewall spacers to expose the semiconductor layer between the raised source and drain regions and the gate, and forming a stress layer overlying the gate and the raised source and drain regions. The stress layer may contact the semiconductor layer between the raised source and drain regions and the gate.

### FIELD OF THE INVENTION

The present invention relates to the field of electronic devices and, more particularly, to semiconductor devices and related methods.

### BACKGROUND OF THE INVENTION

Some semiconductor devices utilize semiconductor-on-insulator (SOI) technology, in which a thin layer of a semiconductor (typically having a thickness of a few nanometers), such as silicon, is separated from a semiconductor substrate by a relatively thick electrically insulating layer (typically featuring a thickness of a few tens of nanometers). Integrated circuits using SOI technology offer certain advantages compared to traditional “bulk” technology for Complementary Metal Oxide Semiconductor (CMOS) integrated circuits. For example, SOI integrated circuits typically provide a lower power consumption for a same performance level.

SOI circuits may also feature a reduced stray capacitance, allowing an increase of commutation speeds. Furthermore, the latch-up phenomena encountered in bulk technology may be mitigated. Such circuits are commonly used in System on Chip (SoC) and Micro electro-mechanical systems (MEMS) applications. SOI circuits may also be less sensitive to ionizing radiations, making them more reliable than bulk-technology circuits in applications where radiation may induce operating problems (e.g., aerospace applications). SOI integrated circuits may include memory components such as Static Random Access Memory (SRAM), as well as logic gates.

One particular type of SOI technology that is helping to allow for continued CMOS scaling is fully depleted SOI (FDSOI). As opposed to a partially depleted SOI (PDSOI) device, in an FDSOI device a relatively thin semiconductor channel film is provided over the buried oxide (BOX) layer, such that the depletion region of the device covers the whole film. FDSOI devices may provide advantages such as higher switching speeds and a reduction in threshold voltage roll off, as compared to PDSOI devices, for example.

One example FDSOI configuration is set forth in U.S. Pat. Pub. No. 2013/0193514 to Loubet et al. This reference discloses a method for making an FDSOI device in which an SOI substrate has a first region isolated from a second region. An SiGe layer is deposited on top of the SOI substrate in the second region. The substrate is subjected to a thermal oxidation process which drives in Ge from the SiGe layer to form an SiGeOI structure in the second region and an overlying oxide layer. If the SOI substrate is exposed in the first region, the thermal oxidation process further produces an oxide layer overlying the first region. The oxide layer(s) is(are) removed to expose an Si channel layer in the first region and an SiGe channel layer in the second region. Transistor gate stacks are formed over each of the Si channel layer and SiGe channel layer. Raised source and drain regions are formed from the Si channel layer and SiGe channel layer adjacent the transistor gate stacks.

Despite the existence of such configurations, further enhancements in SOI devices may be desirable in some applications.

### SUMMARY OF THE INVENTION

A method for making a semiconductor device may include forming a gate on a semiconductor layer, forming sidewall spacers adjacent the gate, and forming raised source and drain regions defining a channel in the semiconductor layer under the gate. The raised source and drain regions may be spaced apart from the gate by the sidewall spacers. The method may further include removing the sidewall spacers to expose the semiconductor layer between the raised source and drain regions and the gate, and forming a stress layer overlying the gate and the raised source and drain regions. The stress layer may contact the semiconductor layer between the raised source and drain regions and the gate.

More particularly, the semiconductor layer may be carried by a semiconductor substrate with a buried oxide layer therebetween defining a semiconductor-on-insulator (SOI) wafer. By way of example, the SOI wafer may comprise a fully depleted SOI (FDSOI) wafer. Forming the sidewall spacers may include forming a respective composite sidewall spacer adjacent each opposing side of the gate. Furthermore, forming the gate may include forming a gate dielectric on the semiconductor layer over the channel, and forming a metal gate electrode on the gate dielectric.

The method may further include forming a silicide layer on the raised source and drain regions. The stress layer may comprise a compressive stress layer or a tensile stress layer. By way of example, the semiconductor layer may comprise at least one of silicon and germanium.

A related semiconductor device may include a gate on a semiconductor layer, and raised source and drain regions defining a channel in the semiconductor layer under the gate. The raised source and drain regions may be spaced apart from the gate. A stress layer may overlie the gate and the raised source and drain regions, and contact the semiconductor layer between the raised source and drain regions and the gate.

### BRIEF DESCRIPTION OF THE DRAWINGS

FIG. 1 is cross-sectional diagram of a semiconductor device in accordance with an example embodiment.

FIGS. 2-3 are a series of cross-sectional diagrams illustrating an example method of making the semiconductor device of FIG. 1.

FIG. 4 is a flow diagram corresponding to the method shown in FIGS. 2-3.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

By way of background, FDSOI technology is one of the driving forces for continued CMOS scaling. In FDSOI devices, performance is affected by the amount of strain/stress that can be applied to the channel. Typical methods for inducing stress in the channel of a semiconductor device include a silicon-germanium channel layer (cSiGe), embedded source/drain, stress liners, etc. However, the embedded source drain approach is not applicable to FDSOI devices, as there is no substrate deep below the channel surface for epitaxial growth. As the channel thickness becomes thinner, and with a smaller pitch, conventional stress liners generally become less effective. Furthermore, the raised source/drain that is typically used in the FDSOI device structure to reduce source/drain resistance may further degrade the stress liner effect.

Generally speaking, an approach is provided herein to make the proximity of the stress liner to the channel area much closer, to thereby enhance the stress impact. The added stress may further improve FDSOI device performance, in addition to providing inherently better electro-statics from the fully depleted nature of the device. However, it should be noted that the techniques described herein may be used for semiconductor devices other than FDSOI or SOI, as will be appreciated by those skilled in the art.

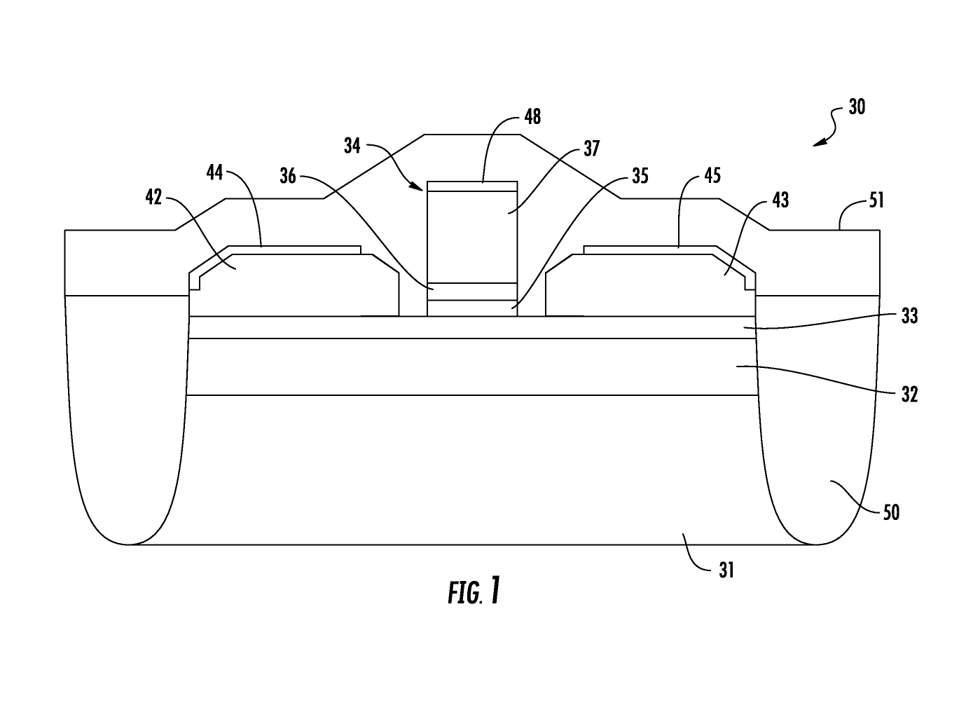

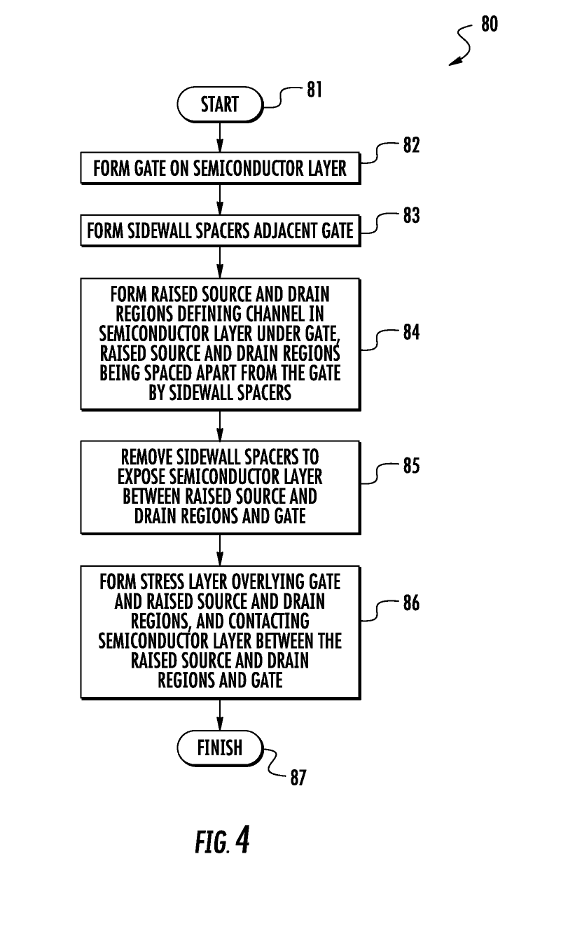

Referring to FIGS. 1-4, an FDSOI device 30 and associated method for making the device are now described. Beginning at Block 81 of the flow diagram 80, the device 30 may be formed on an ultra-thin body and buried oxide (UTBB) FDSOI wafer, which illustratively includes a semiconductor substrate 31 (e.g., a silicon substrate), a BOX layer 32 carried on the substrate, and a semiconductor layer 33 on the BOX layer. By way of example, for an NMOS device, the semiconductor layer 33 may be a silicon layer, and for a PMOS device the semiconductor layer may be a SiGe layer, although different semiconductors may be used in different embodiments, as will be appreciated by those skilled in the art. Also by way of example, a typical thickness of the BOX layer 32 may be in a range of about 10 to 25 nm, while the semiconductor layer 33 may have a thickness in a range of about 3 to 10 nm, for example, although other dimensions may also be used. Shallow trench isolation (STI) regions 50 may also be formed in the UTBB wafer to insulate adjacent MOSFETs from one another.

A gate 34 is formed on the semiconductor layer 33 over the location where the channel is to be defined in the semiconductor layer, at Block 82. The gate stack illustratively includes a low K dielectric layer 35 on the semiconductor layer 33, a high K dielectric layer 36, and a gate electrode 37 on the high K dielectric layer, as will be appreciated by those skilled in the art. In the illustrated example, the gate electrode 37 is a metal gate electrode, although other gate configurations may also be used in different embodiments.

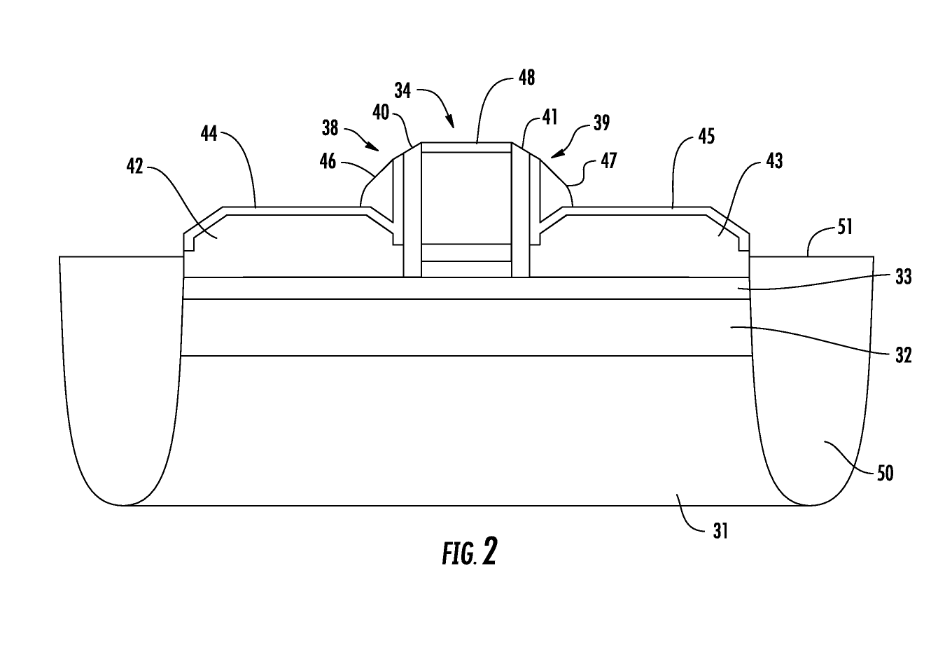

Sidewall spacers 38, 39 are formed adjacent the gate 34 (Block 83). More particularly, the sidewall spacers 38, 39 in the illustrated example are respective composite sidewall spacers adjacent each opposing side of the gate 34 which that are formed by depositing respective inner sidewall nitride (e.g., SiN) layers 40, 41 (FIG. 2). After formation of raised source and drain regions 42, 43 (e.g., via epitaxial growth), at Block 84, formation of the composite sidewall spacers 38, 39 may continue with the formation of first and second silicide layers 44, 45 respectively on the source region 42/inner nitride layer 40 and the drain region 43/inner nitride layer 41. A silicide gate contact layer 48 may also be formed at this time. The composite sidewall spacers 38, 39 may be completed with the formation of outer sidewall nitride layers 46, 47 on the first and second silicide layers 44, 45, as seen in FIG. 2. It should be noted that composite sidewall spacers 38, 39 need not be used in all embodiments, e.g., the inner sidewall spacers 40, 41 may be used without the outer sidewall nitride layers 46, 47 in some configurations.

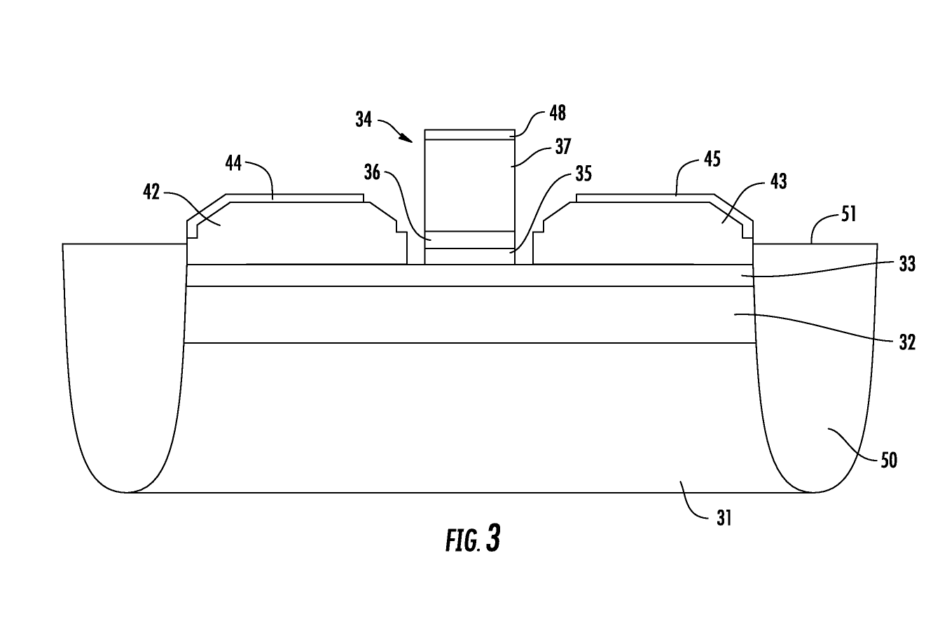

In a conventional FDSOI implementation, at this point a stress layer would typically be deposited over top of the first and second silicide layers 42, 43, the composite sidewall spacers 38, and the silicide gate contact layer 48. Yet, as shown in FIG. 3, in the example method, the composite sidewall spacers 38, 39, are instead removed to expose the semiconductor layer 33 on either side of the gate 34, at Block 85. As such, when a stress layer or liner 51 (e.g., SiN) is deposited over top of the first and second silicide layers 42, 43 and the silicide gate contact layer 48, this stress layer is in direct contact with the semiconductor layer 33 in close proximity to the channel (i.e., on either side of the gate 34). As a result of the direct proximity of the stress layer 51 to the channel, increased strain is created to boost device performance, as will be appreciated by those skilled in the art. Either a compressive or tensile stress layer 51 may be used, depending on the given configuration (e.g., p-channel or n-channel). Moreover, in some embodiments, a compressive material may be used in some locations, while a tensile material is used in another, or compressive and tensile materials may overlap or be intermixed in some locations.

With respect to removal of the sidewall spacers 38, 39, the inner and outer nitride layers 40, 41 and 46, 47 may be removed using a wet etch, or a combination of a dry reactive ion etch (RIE) and a wet etch. For example, HFEG (HF diluted by ethylene glycol) may be used as a wet etch, which is selective to poly silicon, HK (HfO₂), and the metal gate material (e.g., TiN). A selective RIE may also be used to remove the inner and outer nitride layers 40, 41 and 46, 47, and a wet clean (e.g., HFEG) may be used to clean up residuals, for example.

The above-described approach may have certain advantages. One is that conventional processing steps may be used, along with an additional step of removing the sidewall spacers 38, 39 prior to formation of the stress layer 51. Thus, not only does this approach provide for a relatively easy integration, but it may also provide for a boost in device performance by increasing strain, which is typically difficult to achieve in FDSOI device structures.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1-13. (canceled)

14. A semiconductor device comprising:
a semiconductor layer;
a gate on the semiconductor layer;
raised source and drain regions above the semiconductor layer defining a channel in the semiconductor layer under the gate, the raised source and drain regions being spaced apart from the gate; and
a stress layer overlying the gate and the raised source and drain regions, and contacting the semiconductor layer between the raised source and drain regions and the gate.

15. The semiconductor device of claim 14 further comprising a substrate and a buried oxide layer carried on the substrate; and wherein the semiconductor layer is carried on the buried oxide layer.

16. The semiconductor device of claim 14 wherein the gate comprises a gate dielectric on the semiconductor layer over the channel, and a metal gate electrode on the gate dielectric.

17. The semiconductor device of claim 14 further comprising a respective silicide layer on each of the raised source and drain regions.

18. The semiconductor device of claim 14 wherein the stress layer comprises a compressive stress layer.

19. The semiconductor device of claim 14 wherein the stress layer comprises a tensile stress layer.

20. The semiconductor device of claim 14 wherein the semiconductor layer comprises at least one of silicon and germanium.
